(19) United States
(12) Patent Application Publication
(10) Pub. No.: US 2026/0293614 A1
(43) Pub. Date: Sep. 24, 2026

(54) METHOD AND SYSTEM OF ENDPOINT DETECTION IN ETCHING PROCESS

(71) Applicant: Tokyo Electron Limited, Tokyo (JP)

(72) Inventors: Joshua Baillargeon, Albany, NY (US); Hamed Hajibabaeinajafabadi, Albany, NY (US)

(21) Appl. No.: 19/571,181

(22) Filed: Mar. 18, 2026

Related U.S. Application Data
(60) Provisional application No. 63/774,552, filed on Mar. 19, 2025.

(51) Int. Cl. H10P 74/00; G03F 7/004; G03F 7/36; G03F 7/38; H10P 50/28

(52) U.S. Cl. CPC H10P 74/238; G03F 7/0043; G03F 7/36; G03F 7/38; H10P 50/285

(57) ABSTRACT

In an embodiment, a method is provided for etching a substrate. The method includes loading a substrate comprising a first layer in an etch chamber, the first layer comprising first regions to be removed and second regions to be preserved. A first gas is flowed into the etch chamber to chemically modify the first regions. After reducing a flow rate of the first gas, a second gas is flowed into the etch chamber. A plasma is generated from the second gas to remove the first regions selectively with respect to the second regions. While exposing the first layer to the plasma, optical emission data is collected using an optical emission spectroscopy (OES) detector coupled to the etch chamber. An end point is determined based on the optical emission data, and the etching is stopped in response.

### CROSS-REFERENCE TO RELATED APPLICATIONS

This application claims the benefit of U.S. Provisional Application No. 63/774,552, filed on Mar. 19, 2025, which application is hereby incorporated herein by reference.

### TECHNICAL FIELD

The present invention relates generally to the field of semiconductor manufacturing and semiconductor devices, and, in particular embodiments, to methods of end point detection (EPD) in etching process.

### BACKGROUND

Photolithography is commonly used to pattern thin films during semiconductor processing, where photons are emitted from a light source onto a photosensitive photoresist to initiate a chemical reaction in the photoresist. Thereafter, the photoresist is developed and exposed or unexposed regions of the photoresist are removed to form a pattern or a mask.

Scaling of semiconductor devices has enabled significant technological advances, including advanced lithographic techniques such as immersion lithography. Extreme Ultraviolet (EUV) radiation can be used for providing improved pattern resolution in advanced integrated circuits where reduction in feature sizes is required. Common EUV photoresists are polymer-based chemically amplified resists (CARs) that are deposited on substrates using liquid-based spin-on techniques that consume a significant amount of complex precursors. Recently, inorganic-based resists, for example, metal oxide photo resist (MOR), have received interest as they may be patterned using EUV radiation and can offer the high etch resistance and etch selectivity needed for semiconductor manufacturing. However, processing of inorganic-based resists presents new challenges.

### SUMMARY

In accordance with one aspect of the present invention, a method is provided for etching a substrate. The method includes loading a substrate comprising a first layer in an etch chamber, the first layer comprising first regions and second regions, the first regions to be removed without removing the second regions. The method further includes flowing a first gas into the etch chamber to chemically modify the first regions. After reducing a flow rate of the first gas, a second gas is flowed into the etch chamber. A plasma is generated from the second gas and the first layer is exposed to the plasma to remove the first regions selectively with respect to the second regions. While exposing the first layer to the plasma, optical emission data is collected from the plasma using an optical emission spectroscopy (OES) detector coupled to the etch chamber. An end point for the etching of the first layer is determined based on the optical emission data, and the etching of the first layer is stopped in response to determining the end point.

In accordance with another aspect of the present invention, a method is provided for processing a substrate. The method includes performing a cyclic dual development process in an etch chamber, one cycle of the cyclic dual development process comprising chemically modifying a first layer by flowing a first gas into the etch chamber, flowing a second gas into the etch chamber, generating a plasma from the second gas in the etch chamber, collecting optical emission data from the plasma using an optical emission spectroscopy (OES) detector, and determining an end point for the cyclic dual development process based on the optical emission data. The method further includes stopping the cyclic dual development process in response to determining the end point has been reached and transferring the pattern in the first layer to a second layer of the substrate through additional etching processes.

In accordance with yet another aspect of the present invention, a method of endpoint detection during an etch process is provided. The method includes performing a scan using an optical emission spectroscopy (OES) detector across a wavelength range to generate baseline spectral data before etching a photo resist layer in an etch chamber, flowing a first gas into the etch chamber to chemically modify the photo resist layer, purging the etch chamber of the first gas and flowing a second gas into the etch chamber, generating a plasma from the second gas to continue etching the photo resist layer, collecting real-time optical emission data from the plasma, and determining an end point based on intensity changes of the real-time optical emission data relative to the baseline spectral data.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1G illustrate cross-sectional views of a method of processing a substrate, in accordance with one embodiment;

FIGS. 2A and 2B illustrate cross-sectional views of an etch stop layer removal process, in accordance with one embodiment;

FIG. 3 is a flowchart of a method of processing a substrate, in accordance with one embodiment;

FIG. 4 is a flowchart of another method of processing a substrate, in accordance with one embodiment;

FIG. 5 is a schematic illustration of a system of processing a substrate, in accordance with one embodiment;

FIG. 6 illustrates exemplary data of etching exposed and unexposed regions of a photo resist layer under different process conditions, in accordance with one embodiment;

FIG. 7 illustrates exemplary optical emission data during etching a photo resist layer, in accordance with one embodiment;

FIGS. 8A-8B illustrate exemplary optical emission data and thickness of a photo resist layer after an etch process of different RF powers, in accordance with one embodiment; and

FIGS. 9A-9B illustrate exemplary data of etch amount using different processes, in accordance with one embodiment.

Corresponding numerals and symbols in different figures generally refer to corresponding parts unless otherwise indicated. The figures are drawn to clearly illustrate the relevant aspects of the embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

In various embodiments, methods and systems are provided for endpoint detection during metal oxide photo resist (MOR) etch processes in semiconductor device fabrication. Conventional gas-based etch processes for MOR materials rely on timed etching without real-time monitoring capabilities. These timed etch processes are susceptible to variations arising from multiple factors, including MOR material properties, etch chamber conditions, and chamber cleaning cycles between lots. Such variations can lead to inconsistent etching results and reduced process control.

While optical emission spectroscopy (OES) monitoring through exhaust systems has been implemented in gas-based etch processes, this approach presents limitations due to its dependence on chamber cleaning effectiveness and byproduct evacuation efficiency. In one or more embodiments, a dual development process combines gas-based treatment step and plasma-based etch to enable detection of metal byproducts during MOR processing. In particular, the gas-based treatment step modifies the MOR material by forming, for example, brominated tin compounds. Subsequently, the plasma-based etch converts the brominated tin compounds into volatile hydrogen-containing tin species. These hydrogen-containing species exhibit enhanced optical emission characteristics compared to halogenated tin compounds generated during conventional etching processes. The distinct optical characteristics of the hydrogen-containing tin species enable more sensitive and reliable OES detection.

The dual development process provides selective MOR development while enabling real-time monitoring of metal-containing byproducts removed from the substrate surface. By incorporating OES directly coupled to the etch chamber rather than relying on exhaust monitoring systems, the process enables precise monitoring of the etching progression and accurate endpoint detection. This direct monitoring approach eliminates the limitations associated with exhaust-based detection methods and provides improved process control capabilities.

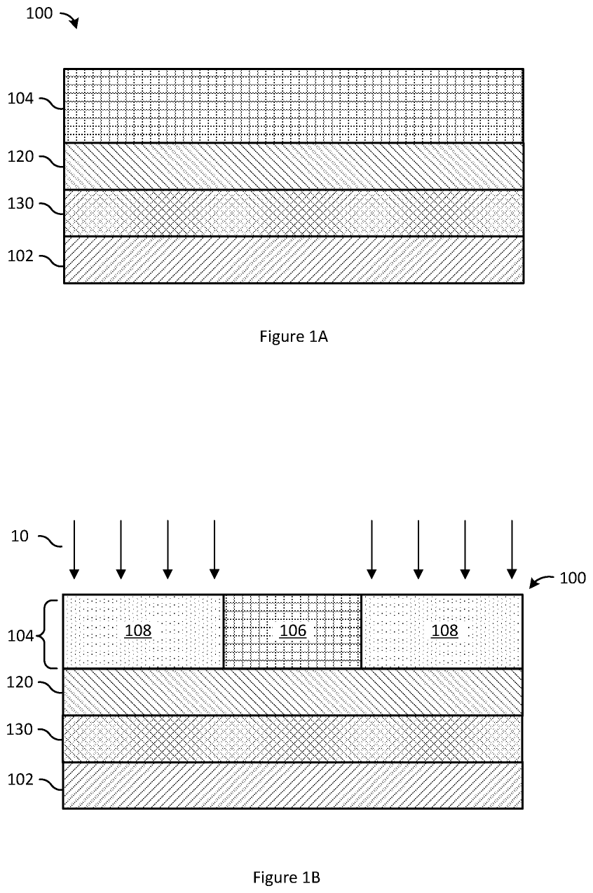

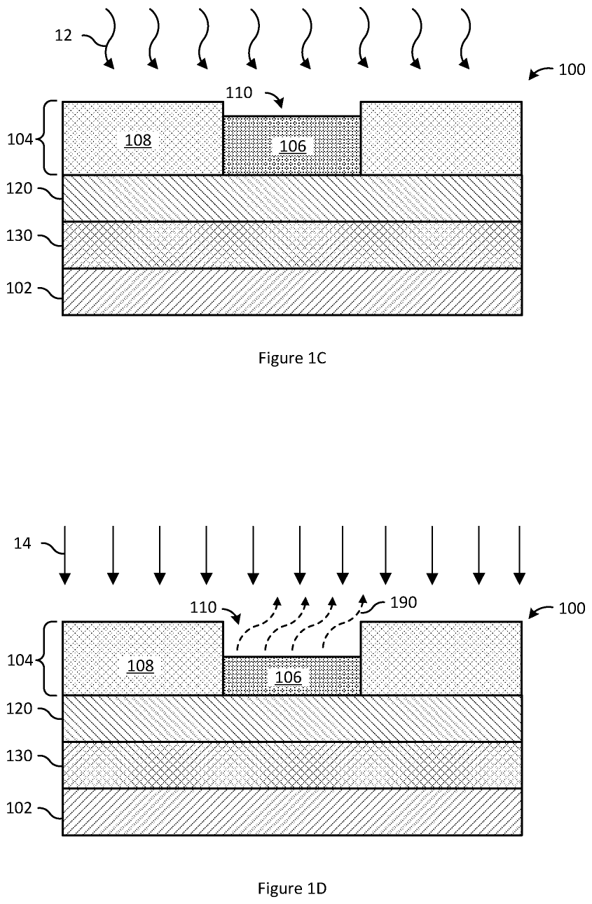

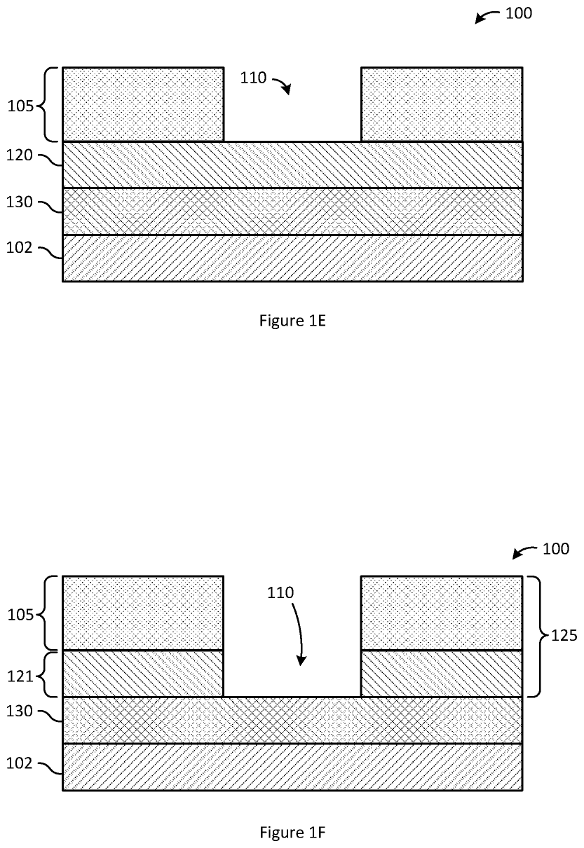

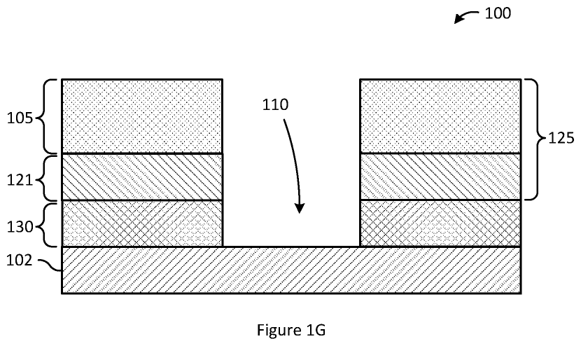

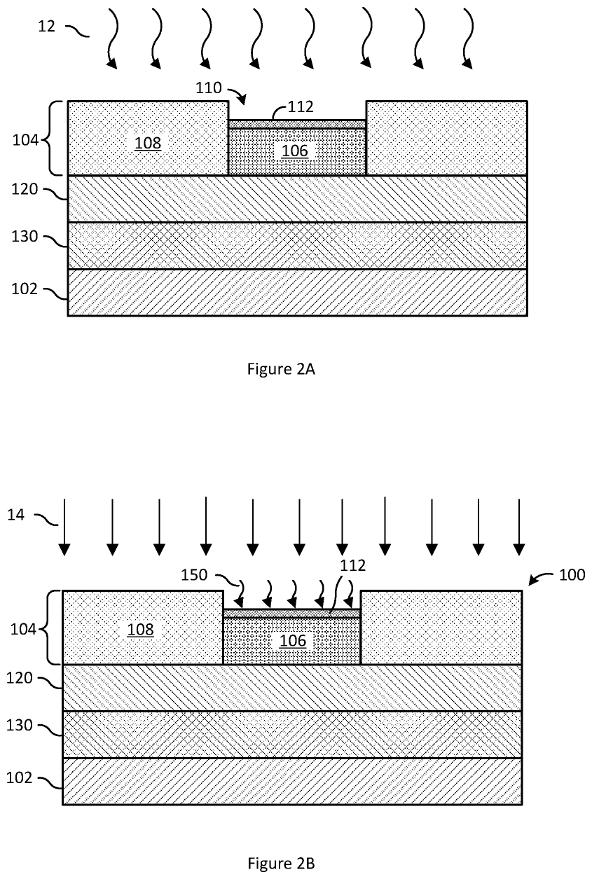

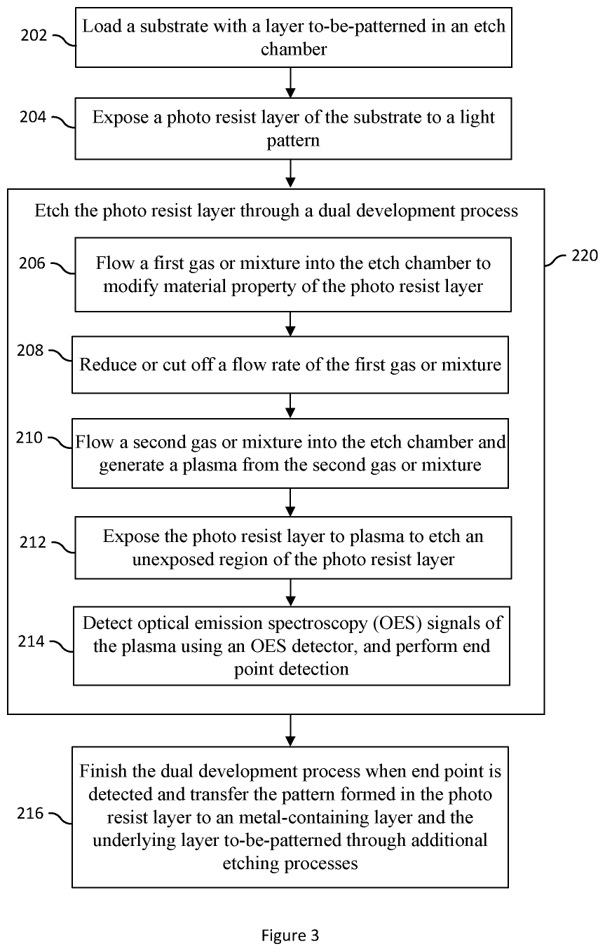

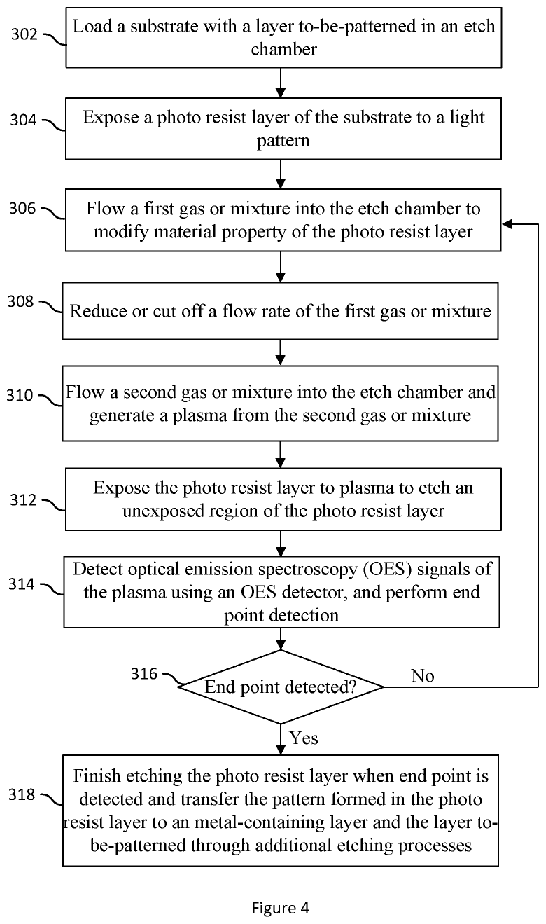

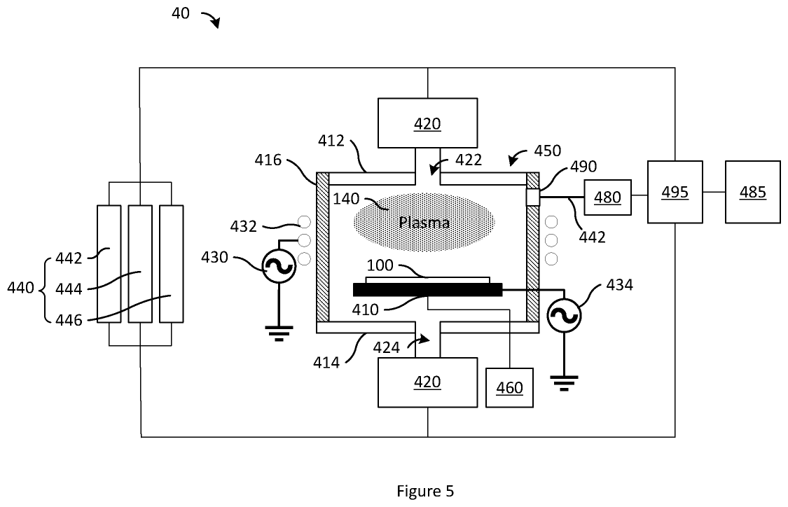

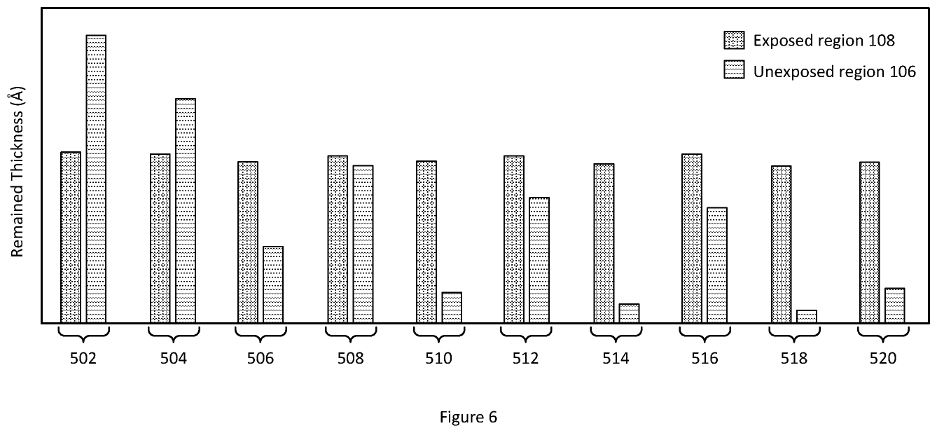

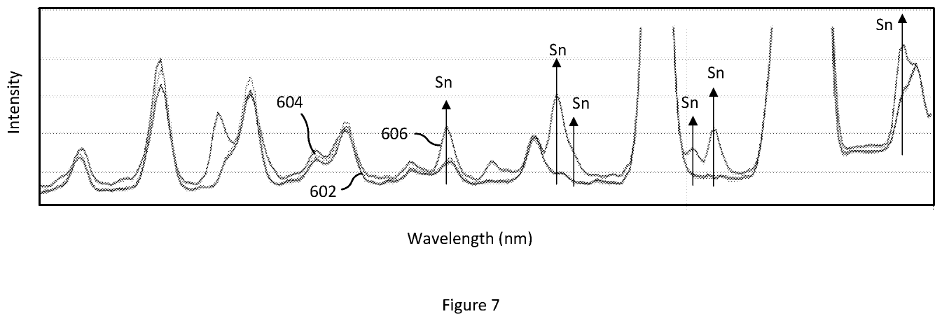

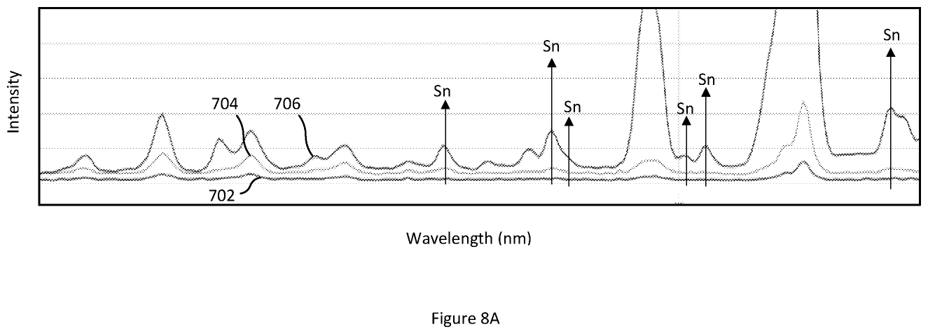

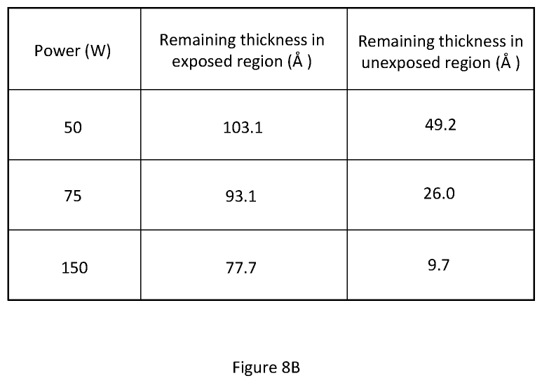

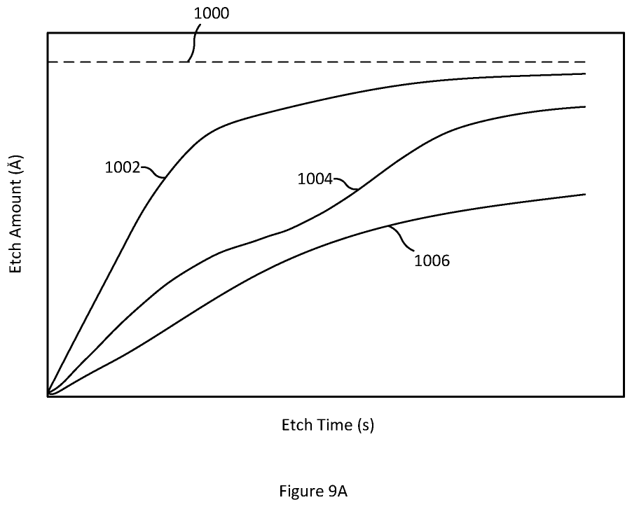

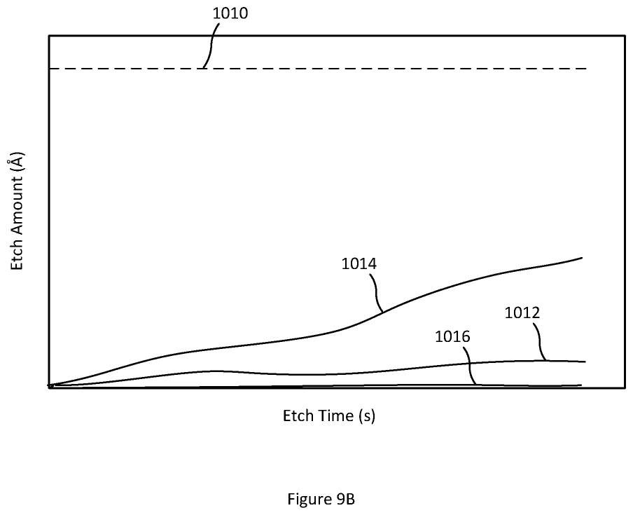

Embodiments of the disclosure are described in the context of the accompanying drawings. An embodiment of processing a substrate including formation and etching a substrate is described using FIGS. 1A-1G. An embodiment etch stop layer removal process is illustrated in FIGS. 2A and 2B. Embodiments of methods for processing a substrate including the dual development process and endpoint detection are described using FIGS. 3 and 4. An embodiment system to process the substrate is illustrated in FIG. 5. Embodiments of exemplary data of etching a photo resist layer under different conditions are illustrated in FIG. 6. Embodiments of exemplary data of optical emission data during the etch process are presented in FIG. 7. Embodiments of exemplary data of optical emission data and thickness of a photo resist layer under different RF powers are illustrated in FIGS. 8A and 8B. Embodiments of exemplary data of etch amount using different processes are illustrated in FIGS. 9A and 9B.

In accordance with various embodiments, FIGS. 1A-1G illustrate cross-sectional views of steps of an example method to process a substrate 100 in an etch chamber, and FIG. 3 provides a flow diagram of the corresponding process steps.

Referring to FIG. 1A and block 202 of FIG. 3, in some embodiments, a layer to-be-patterned 130 may be disposed over a substrate layer 102. The layer to-be-patterned 130 may represent a layer that will be subsequently patterned. In some embodiments, an underlayer 120 may be disposed over the layer to-be-patterned 130. In some embodiments, the underlayer 120 may help to improve the efficiency of the exposure to EUV radiation by enhancing photon absorption or reducing reflections. A photo resist layer 104 may be disposed over the underlayer 120. As described below in greater detail, the photo resist layer 104 will be patterned in subsequent steps to define the desired features. In various embodiments, a photo resist layer may also be referred to below as a first layer, and a layer to-be-patterned may also be referred to below as a second layer.

In one or more embodiments, the substrate layer 102 may be a silicon wafer, or a silicon-on-insulator (SOI) wafer. In certain embodiments, the substrate layer 102 may comprise silicon germanium, silicon carbide, gallium arsenide, gallium nitride, or other compound semiconductors. In other embodiments, the substrate layer 102 may comprise heterogeneous layers such as silicon germanium on silicon, gallium nitride on silicon, silicon carbon on silicon, as well layers of silicon on a silicon or SOI substrate. In various embodiments, the substrate layer 102 may be patterned or embedded in other components of the semiconductor device.

In various embodiments, the layer to-be-patterned 130 may comprise materials such as dielectric materials, metal-based materials, organic materials, or a combination thereof. Dielectric materials may include tetraethyl orthosilicate (TEOS), silicon dioxide, silicon nitride, silicon oxynitride, silicon carbide, amorphous silicon, polycrystalline silicon, or the like. Metal-based materials may include titanium, titanium-based compounds, tantalum, tantalum-based compounds, tungsten, tungsten-based compounds, ruthenium, ruthenium-based compounds, aluminum, aluminum-based compounds, or the like. Organic materials may include spin-on carbon, amorphous carbon, or organic planarization layers. In various embodiments, the layer to-be-patterned 130 may serve as a target layer for device fabrication or as a hardmask layer for transferring patterns to underlying device layers. The layer to-be-patterned 130 may comprise either a single layer or a stacked structure comprising two or more layers of different materials. For example, in a multi-layer configuration, the stack may include a combination of metal-based layers, dielectric layers, and organic layers arranged to facilitate pattern transfer and etch selectivity.

The deposition of the layer to-be-patterned 130 may be achieved through various suitable processes. In some embodiments, the layer to-be-patterned 130 may be deposited using spin-on coating techniques, chemical vapor deposition (CVD), atomic layer deposition (ALD), plasma-enhanced CVD (PECVD), plasma-enhanced ALD (PEALD), a combination thereof, or the like. The choice of deposition method depends on factors such as the desired thickness, uniformity, and material properties of the layer to-be-patterned 130.

In one or more embodiments, the underlayer 120 may comprise a single layer. In various embodiments, the underlayer 120 may comprise organic materials, silicon-containing materials, metal-containing materials, or a combination thereof. In other embodiments, the underlayer 120 may comprise a single layer of organic material, such as a spin-on organic dielectric layer (ODL), or a silicon-based anti-reflective coating (SiARC). The silicon-containing materials may include silicon-based anti-reflective coatings (SiARC), silicon oxynitride, silicon dioxide, silicon nitride, or the like. The metal-containing materials may comprise titanium, hafnium, aluminum, zirconium, or the like. The underlayer 120 may serve as an anti-reflective coating, an adhesion layer, a planarization layer, an etch stop layer, or an intermediate layer for pattern transfer.

The deposition of the underlayer 120 can be accomplished through various methods. In some embodiment, physical vapor deposition (PVD), CVD, ALD, spin-on deposition techniques, a combination thereof, or the like may be employed. The choice of deposition method depends on factors such as the desired thickness, uniformity, and material properties of the underlayer 120. In some embodiments, the underlayer 120 may have a thickness in a range from 1 nm to 100 nm, for example, 5 nm to 50 nm. In various embodiments, when the underlayer 120 comprises organic materials, the thickness may be in a range from 5 nm to 50 nm.

In various embodiments, the photo resist layer 104 may be a layer of metal oxide photo resist (MOR) comprising tin (Sn), antimony (Sb), hafnium (Hf), zirconium (Zr), zinc (Zn), the like, or a combination thereof. In certain embodiments, the photo resist layer 104 may comprise a metal oxide, a metal alkoxide, or a methacrylate (MAA) of Sn, Sb, Hf, Zr, Zn, or the like, such as ZrMAA, SbMAA, SbMAA: F, HfMAA, ZnMAA, and ZnMAA: F. In certain embodiments, the photo resist layer 104 may be a network of metal oxides comprising a metal alkoxide, metal alkenoxide, metal aryloxide, or metal carboxylate group. These groups bonded to the metal are generally represented by chemical formulas, —OR, —OR′, —OAr, and —OOCR, respectively, where R is an alkyl group, R′ is an alkene group, and Ar is an aryl group. In various embodiments, the photo resist layer 104 may be a polymeric film, and may not have a highly ordered structure such as crystalline. The number of the above functional groups bonded to the metal atom may differ for each metal atom, ranging between 1 and 4. The deposition of the photo resist layer 104 may be performed by a dry or wet process. In various embodiments, the photo resist layer 104 may be deposited by vapor deposition, for example, chemical vapor deposition (CVD), plasma-enhanced CVD (PECVD), atomic layer deposition (ALD), or plasma-enhanced ALD (PEALD).

In certain embodiments, the deposition process for the photo resist layer 104 (e.g., the layer of MOR) may comprise exposing the substrate layer 102 to two precursors in a deposition chamber: a metal-containing precursor (e.g., a tin-containing precursor) and an oxygen-containing precursor. The exposures to these precursors may be performed stepwise or simultaneously. In various embodiments, the deposition process may be an ALD or pseudo-ALD process and may comprise two or more exposing steps. For example, the deposition process may be performed by first exposing the substrate layer 102 to the tin-containing precursor that forms an adsorbed layer on the substrate layer 102 and, thereafter, exposing the substrate layer 102 to the oxygen-containing precursor gas that reacts with the adsorbed tin-containing precursor. The exposing steps may be repeated one or more times to increase a thickness of the photo resist layer 104 on the underlayer 120. In certain embodiments, the exposing steps may be separated temporally or spatially. Temporally separating the exposing steps may be realized by changing the gas composition in a etch chamber. On the other hand, spatially separating the exposing steps may be enabled by utilizing multiple spatially segregated sections within the etch chamber and transporting the substrate from one section to another. For temporally separating the exposing steps even better, the vapor deposition may further include evacuating, purging, or both evacuating and purging, the etch chamber between the exposing steps. These additional steps may be beneficial in ensuring the reaction occurs only on surface and not in the gas phase. The ALD or pseudo-ALD method in accordance with this embodiment may be particularly advantageous in enabling layer-by-layer growth of the photo resist layer 104 with a high uniformity.

In other embodiments, the photo resist layer 104 (e.g., the layer of MOR) may be deposited by liquid deposition using alternate exposures of a tin-containing precursor liquid and an oxygen-containing precursor liquid. The liquid deposition may further include rinsing the substrate with a rinsing solution to remove an excess amount and/or unreacted portion of the precursors between the exposing steps. The rinsing solution may comprise deionized water, common organic solvents such as acetone, propylene glyclol monomethyl ether acteate, 1-Methoxy-2-propanol, methyl isobutyl carbinol, hexane, tert-butanol and isopropanol, or mixtures thereof. In another embodiment, the liquid precursors may be mixed first and the mixture solution may be applied to the substrate to grow the photo resist layer 104. In one or more embodiments, one of the precursors may be gaseous and another of the precursors may be liquid, and accordingly two different modes (vapor and liquid) of delivery may be utilized to perform the deposition process.

In various embodiments, after forming the photo resist layer 104, an optional post-apply bake may be performed to remove any excess solvents from a wet process, residual volatile byproducts from a dry process, or both.

As illustrated in FIG. 1B and corresponding to block 204 of FIG. 4, the photo resist layer 104 may be exposed to a light pattern 10, such as an EUV light pattern. A photomask may be used to create the light pattern 10 by placing the photomask between the photo resist layer 104 and an EUV light source (not illustrated). In response to the exposure to the light pattern 10, a photoreaction may occur in exposed regions 108 of the photo resist layer 104, while unexposed regions 106 remain unchanged. As a result of the photoreaction, the exposed regions 108 may comprise a cross-linked photoresist film, which may have material properties substantially different from the unreacted portion of the photo resist layer 104 (i.e., the unexposed regions 106). Such a difference in the material properties includes volatility, reactivity, and/or solubility among others, which gives origin to the tonality as a photoresist. In various embodiments, unexposed regions may also be referred to below as first regions, and exposed regions may also be referred to below as second regions.

In various embodiments, after the exposure to the light pattern 10, a post-exposure bake (PEB) may be performed on the photo resist layer 104. The PEB may be performed at a temperature in a range from 150° C. to 250° C. for a duration of 30 seconds to 300 seconds. In an embodiment, the PEB temperature and duration may affect the degree of cross-linking in the exposed regions 108 and may influence the subsequent gas-based modification and plasma-based etch steps. In various embodiments, higher PEB temperatures or longer PEB durations may increase cross-linking in the exposed regions 108, which can reduce material removal during the gas-based modification step while maintaining or enhancing selectivity during the plasma-based etch step. The PEB conditions may be selected based on factors such as the specific MOR material composition, desired pattern resolution, and target selectivity between exposed and unexposed regions.

As illustrated in block 220 of FIG. 3, in various embodiments, after the light exposure (see above, FIG. 1B), the substrate 100 may be patterned with a dual development process. In some embodiments, FIG. 1C and block 206 illustrate a first step of the dual development process which may be a gas-based modification step by flowing a first gas 12 into the etch chamber at a first flow rate. The first gas 12 may chemically modify the unexposed regions 106 of the photo resist layer 104 by incorporating halogen atoms into the metal oxide photo resist material, forming brominated or halogenated tin compounds. In various embodiments, this chemical modification creates a modified material within the unexposed regions 106 that exhibits enhanced reactivity and volatility during the subsequent plasma-based etch step. In various embodiments, the first gas 12 may be a halogen-containing gas that incorporates halogen atoms into the metal oxide photo resist material. In an example, if the first gas 12 comprises hydrogen bromide (HBr) and the photo resist layer 104 comprises a tin-based metal oxide resist, the gas-based modification step may form a mixed oxo-tin-bromide intermediate species within the unexposed regions 106. In various embodiments, this intermediate species may comprise partially brominated tin compounds where the tin atom retains some oxide or hydroxide bonding, such as RSnO/RSnOOH reacted with HBr to form a non-volatile mixed oxo-tin-bromide species. In some embodiments, the partially brominated intermediate may result from incomplete bond substitution, where unsaturated tin bonding sites created during the modification step render the material more susceptible to attack by hydrogen species during the subsequent plasma-based etch. In some embodiments, the first gas 12 may also partially remove material from the unexposed regions 106, though the primary function of this step is to chemically alter the material composition rather than to achieve substantial material removal. The modified unexposed regions 106 may comprise partially brominated species that are more readily removed during plasma exposure compared to unmodified material. In various embodiments, even though both the exposed regions 108 and the unexposed regions 106 may be modified, the chemical contrast between the exposed regions 108 and unexposed regions 106 remains sufficient to enable selective removal during the subsequent plasma-based etch.

In some embodiments, the first gas 12 may comprise a halogen-containing gas such as hydrogen iodide (HI), hydrogen bromide (HBr), hydrogen chloride (HCl), boron trichloride (BCl₃), boron tribromide (BBr₃), or the like. In other embodiments, the first gas 12 may comprise an organic acid such as acetic acid, trifluoroacetic acid, hexafluoroacetylacetone, acetylacetone, or the like. In various embodiments, combinations of different halogen-containing gases or acids may be employed. The chemical modification may occur throughout the bulk of the unexposed regions 106 due to the porous nature of the metal oxide photo resist material, allowing the small molecules of the first gas 12 to penetrate and react with the material. In an embodiment, the unexposed regions 106 may have a more porous structure compared to the exposed regions 108, facilitating deeper penetration and more extensive modification of the unexposed regions 106.

In various embodiments, flow rates of the first gas 12 may be between 10 sccm and 2000 sccm. In various embodiments, a chamber pressure during the gas-based modification treatment may be between 10 mTorr and 800 mTorr. In an embodiment, chamber pressures greater than 200 mTorr may be preferred for shorter modification times. In various embodiments, the gas-based treatment may be performed at a temperature in the etch chamber in a range of −50° C. to 120° C., for example, −50° C. to 10° C. In an embodiment, lower temperatures such as 10° C. or below may provide enhanced selectivity between the exposed regions 108 and unexposed regions 106 by reducing unwanted modification or removal of the exposed regions 108. In various embodiments, temperatures below 0° C. may be employed to further improve selectivity. Higher temperatures such as 60° C. or above may reduce or eliminate formation of certain surface species but may also reduce selectivity between exposed and unexposed regions. In various embodiments, the gas-based modification treatment may be performed for a duration of 5 seconds to 100 seconds. In an embodiment, shorter durations such as 10 seconds to 30 seconds may be applied to achieve the desired degree of material modification without excessive material removal.

FIG. 1D illustrates a cross-sectional view following the gas-based modification treatment, in accordance with various embodiments. With reference to FIG. 1D and block 208 of FIG. 3, after the gas-based modification treatment, the flow rate of the first gas 12 may be reduced or the first gas 12 may be purged from the etch chamber. In some embodiments, the etch chamber may be evacuated to remove the first gas 12 and gaseous byproducts generated during the modification step before proceeding to the plasma-based etch step. In various embodiments, purging or evacuating the etch chamber between the gas-based modification step and the plasma-based etch step may prevent unwanted reactions between residual halogen-containing gases and the hydrogen-containing gases used in the plasma step. In an embodiment, intermixing of halogen-containing gases such as HBr with hydrogen-containing gases and nitrogen may lead to formation of undesired compounds such as ammonium bromide salts that could deposit on the substrate surface or chamber walls. In various embodiments, the salt formation may be avoided by maintaining adequate purging between the gas-based modification step and the plasma-based etch step, or by controlling chamber pressure and gas flow rates within acceptable ranges during the transition between steps.

With reference to FIG. 1D and corresponding to block 210 of FIG. 3, a second gas may be flowed into the etch chamber. In various embodiments, the second gas may comprise an inert gas such as nitrogen (N₂), argon (Ar), helium (He), or combinations thereof. In one or more embodiments, the second gas may further comprise a hydrogen-containing gas such as hydrocarbon gases, hydrogen (H₂), ammonia (NH₃), hydrazine (N₂H₄), or combination thereof. In various embodiments, the ratio between the inert gas and the hydrogen-containing gas may range from 1:1 to 20:1. The hydrocarbon gases may provide both hydrogen and carbon species to the plasma. In an embodiment, the hydrocarbon gases such as methane (CH₄), ethane (C₂H₆), propane (C₃H₈), butane (C₄H₁₀), or other alkanes/alkenes/alkynes may be used to generate hydrogen radicals through dissociation in the plasma. In various embodiments, the choice of hydrocarbon gas may be selected based on factors such as hydrogen content, dissociation energy, and compatibility with the etch chamber materials. The carbon-containing species generated from hydrocarbon dissociation may also participate in the etch process or form volatile carbon-containing byproducts that are readily removed from the etch chamber. A radio frequency (RF) power source may apply power to generate a plasma 14 from the second gas. In an embodiment, the RF power source may operate at a frequency of 1-30 MHz and deliver power in a range from 50W to 1500W. In some embodiments, the plasma generation may occur at a chamber pressure between 10 mTorr and 1000 mTorr while maintaining a temperature of the substrate 100 between −50° C. and 120° C., for example, −50° C. to 10° C. As illustrated in block 212 of FIG. 3, the plasma 14 may selectively etch the unexposed region 106 of the photo resist layer 104 with respect to the exposed region 108.

In various embodiments, the plasma 14 may interact with the brominated material in the unexposed regions 106 to facilitate selective removal of the unexposed regions 106 with respect to the exposed regions 108. The plasma 14 may produce reactive hydrogen species that react with the brominated tin compounds formed during the gas-based modification step. In an embodiment, the hydrogen radicals generated from the hydrogen-containing gas in the plasma 14 may convert the brominated tin species into hydrogen-containing tin compounds. These reactions may produce byproducts 190 comprising hydrogen-substituted tin compounds such as SnHₓBr_{y} (where 1≤x≤4 and 1≤y≤4) or tin hydride (SnH₄), which exhibit distinct optical emission characteristics in the plasma state. In various embodiments, the conversion from heavily brominated tin compounds to hydrogen-containing tin species enhances the volatility of the byproducts, facilitating their removal from the substrate surface. The hydrogen-containing tin species in the byproducts 190 may be detected by optical emission spectroscopy (OES) for endpoint detection, as described in greater detail below.

In various embodiments, nitrogen (N₂) in the second gas may minimize generation of vacuum ultraviolet (VUV) and extreme ultraviolet (EUV) photons compared to other inert gases such as argon or helium. In various embodiments, VUV and EUV photons can dissociate organic functional groups (R-groups) in the metal oxide photo resist material and cause unwanted cross-linking of the unexposed regions 106. By using nitrogen, which exhibits lower VUV and EUV photon generation, the plasma-based etch step may preserve the chemical contrast between the exposed regions 108 and unexposed regions 106, maintaining selectivity during the removal process. In an embodiment, the nitrogen plasma may also exhibit high vibrational energy states that contribute to energy transfer processes at the substrate surface without generating excessive photon radiation that could modify the exposed regions 108.

In one or more embodiments, another RF power source may apply a bias power to a substrate holder that supports the substrate 100 during the etch process. The application of bias power may create a potential difference between the plasma 14 and the photo resist layer 104, which accelerates ionic species toward the substrate 100 in a directional manner. In various embodiments, the accelerated ion bombardment may enhance the removal of modified material and increase the etch rate. The bias power level may be adjusted to control the ion bombardment energy, thereby optimizing the etching rate and profile. In an embodiment, higher bias powers increase the directionality of the etch process, improving anisotropic etching characteristics and maintaining vertical profile control of the photo resist layer 104. In various embodiments, the bias power may range from 0 W to 500 W. In some embodiments, the bias power may be below 100 W.

FIGS. 2A and 2B illustrate cross-sectional views of an alternative embodiment where an etch stop layer may form during the gas-based modification treatment, in accordance with various embodiments. In some embodiments, depending on the specific MOR material formulation, process conditions, or both, an etch stop layer 112 may accumulate on surfaces of the photo resist layer 104 during the gas-based modification step illustrated in FIG. 1C. The formation and characteristics of the etch stop layer 112 may depend on factors such as the MOR material composition, gas flow rates, chamber pressure, surface temperature, and duration of the gas-based modification treatment.

As illustrated in FIG. 2A, the etch stop layer 112 may form on surfaces of the unexposed regions 106. The etch stop layer 112 may comprise etch-inhibiting species that inhibits the etch process. In various embodiments, the etch stop layer 112 may comprise metal-halide compounds, such as tin-bromine compounds, that are less volatile than the primary treatment byproducts. The formation of etch stop layer 112 may vary in thickness and composition depending on process parameters such as gas flow rates, chamber pressure, and surface temperature. In various embodiments, the etch stop layer 112 may function as a barrier between the first gas 12 and the underlying photo resist layer 104, reducing the chemical reaction rates at the interface. The accumulation of this etch stop layer 112 may decrease chemical reaction rates at the interface and limit further material removal. In one or more embodiments, the presence of etch stop layer 112 may lead to non-uniform removal of the photo resist layer 104, introducing process variations that impact critical dimension control and pattern fidelity.

With reference to FIG. 2B and corresponding to block 210 of FIG. 3, the plasma-based etch step effectively removes the etch stop layer 112 and continues etching the unexposed regions 106. In various embodiments, the plasma 14 generated from the second gas may interact with the etch stop layer 112 to facilitate its removal. The hydrogen radicals in the plasma 14 may react with the metal-halide compounds in the etch stop layer 112, converting them into more volatile hydrogen-containing species that can be removed from the substrate surface. In various embodiments, molecular gases such as nitrogen in the plasma 14 may exhibit high vibrational energy, contributing to localized heating effects 150 onto the etch stop layer 112. These energetic nitrogen molecules may interact with the etch stop layer 112 and transfer vibrational energy through molecular collisions, generating thermal energy at the surface. In various embodiments, molecular nitrogen (N₂) in the plasma 14 may exhibit high vibrational energy that interacts with the etch stop layer 112 through molecular collisions or heating, disrupting the bonding structure or surface species, thereby modifying the MOR stability. The actual removal of the etch stop layer 112 and etching of the unexposed regions 106 may be primarily driven by hydrogen and carbon species generated from the dissociation of hydrocarbon gases such as methane (CH₄) in the plasma 14. In various embodiments, the carbon-containing species from CH₄ dissociation may also provide passivation of the exposed regions 108, contributing to the selectivity of the dual development process. In various embodiments, the dual development process enables effective MOR patterning regardless of whether an etch stop layer forms during the gas-based modification step, providing robust process performance across different MOR material formulations.

In various embodiments, the OES detector coupled to the etch chamber may collect optical emission data through a viewport or optical window positioned to observe the plasma region above the substrate 100 (as illustrated in block 214 of FIG. 3). In one or more embodiments, the OES detector may comprise a spectrometer that measures emission intensities across multiple wavelengths, particularly monitoring specific tin emission lines between 270 nm and 327 nm. In some embodiments, a survey scan using the OES detector may be performed across a wavelength range, e.g., 200 nm to 700 nm, to generate baseline spectral data before etching the photo resist layer. The OES detector may collect real-time optical emission data from the plasma 14 and analyze various plasma characteristics including chemical species concentrations through emission line intensities, plasma density variations through overall emission intensity, and reaction kinetics through temporal emission changes. The OES detector may compare the real-time optical emission data with the baseline spectral data, and determine an end point based on intensity changes in the real-time optical emission data relative to the baseline spectral data. In some embodiments, the changes in metal-containing species emission intensities during the etch process may be used to determine an end point. In one embodiment, a characteristic decrease of the metal-containing species emission intensities during the etch process may be used to determine an end point.

FIG. 1E and block 216 of FIG. 3 show the completion of the dual development process (or etching the photo resist layer 104) to form a patterned photo resist layer 105 where the unexposed region 106 of the photo resist layer 104 has been removed to expose the underlying substrate layer 102. In various embodiments, duration of the plasma-based etch may be 10 seconds to 100 seconds.

Upon determining that the end point has been reached, the dual development process may be stopped as a response. In various embodiments, the etch chamber may initiate a controlled shutdown sequence to prepare for subsequent fabrication processes. In one or more embodiments, the shutdown sequence may include ramping down the RF source power and bias power according to predetermined profiles to prevent sudden plasma extinction that could lead to particle generation. In some embodiments, the flow rates of the second gas may be gradually reduced while maintaining chamber pressure control. In some embodiments, the substrate temperature may be allowed to stabilize toward a handling temperature, for example, between 20° C. and 30° C. In various embodiments, post-etch purge steps may be performed using inert gases to remove residual process gases and byproducts from the etch chamber before subsequent fabrication.

In FIG. 1F and block 216 of FIG. 3, the underlayer 120 may be patterned to form a patterned underlayer 121, such that the pattern of the patterned photo resist layer 105 may be transferred to the patterned underlayer 121. In various embodiments, the patterning of the underlayer 120 to form the patterned underlayer 121 may be achieved through an etching process. The etching process may selectively remove portions of the underlayer 120 that are not protected by the patterned photo resist layer 105, while leaving the protected portions substantially intact. During this patterning process, the opening 110 may penetrate the underlayer 120 and expose a top surface of the layer to-be-patterned 130. In some embodiments, the patterned photo resist layer 105 and the patterned underlayer 121 may serve as a hard mask 125 for subsequent processing steps.

In various embodiments, the etching process to etch the underlayer 120 may be a dry etch process (e.g. reactive ion etching), a wet etch process, a combination thereof, or the like. In some embodiments, depending on the choice of underlayer material and process conditions, the underlayer 120 may be partially or fully removed during the MOR patterning step due to over-etch of the photo resist layer 104. In various embodiments, the underlayer 120 may be etched after inspection of the patterned photo resist layer 105, for example using critical dimension scanning electron microscopy (CDSEM) to evaluate critical dimension uniformity and pattern roughness.

In FIG. 1G and block 216 of FIG. 3, the hard mask 125 comprising the patterned photo resist layer 105 and the patterned underlayer 121 may be used to transfer a pattern of the hard mask 125 to the layer to-be-patterned 130. The transfer process may comprise a suitable etch process while using the hard mask 125 as an etch mask. The suitable etch process may be a dry etch process (e.g. reactive ion etching), a wet etch process, a combination thereof, or the like. In various embodiments, the OES detector may be used to determine an end point during etching the layer to-be-patterned 130 based on methods described above with reference to FIG. 1D.

In various embodiments, the processed substrate 100, now having the desired layer to-be-patterned 130, may be transferred to subsequent fabrication processes such as ion implantation, thin film deposition, or additional etching steps.

In the embodiments described above referring to FIGS. 1A-1G, the photo resist layer 104 is a negative-tone photo resist. In other embodiments, the photo resist layer 104 may be a positive-tone photo resist, where the exposed regions 108 may be removed by the etch process and the unexposed regions 106 remain. In one embodiment, the positive-tone photoresist may be enabled by using a large dose of boron trichloride (BCl₃) at a temperature range of −30° C. to 60° C. (e.g., a dose in a range of 5 sccm to 500 sccm) to increase an etch resistance of the unexposed regions 106 after the EUV exposure, while the photoreaction in the exposed regions 108 may remain substantially unchanged in some embodiments.

While FIG. 3 shows endpoint detection (block 214) after exposing the photo resist layer 104 to plasma (block 212) in a sequential block diagram format, it should be understood that the OES detector may collect optical emission data from the plasma continuously throughout the plasma-based etch. In various embodiments, once the plasma is generated from the second gas, the OES detector may begin collecting and analyzing the optical emission data. In some embodiments, the OES detector may collect the optical emission data without interruption during the entire plasma exposure period. In alternative embodiments, the OES monitoring may collect the optical emission data at frequencies between 1-10 Hz, enabling real-time tracking of tin-containing byproducts and other plasma species. In one or more embodiments, the endpoint detection algorithms may continuously process the collected optical emission data, comparing emission intensities and intensity ratios against predetermined endpoint criteria. Upon detection of endpoint conditions at any time during the etch process, the system may immediately initiate the shutdown sequence to prevent over-etching. In various embodiments, this real-time collection of optical emission data ensures optimal etch profiles and prevents damage to underlying layers that could result from extended plasma exposure after reaching the endpoint condition.

FIG. 4 illustrates a flow diagram of a method for processing a substrate according to another embodiment. The method differs from previous method in FIG. 3 in using a cyclic dual development process to etch the photo resist layer 104.

The method may begin at block 302 with loading the substrate comprising a layer to-be-patterned disposed over a substrate layer in an etch chamber. An underlayer may be formed over the layer to-be-patterned and a photo resist layer may be disposed over the underlayer. The substrate may comprise the same structures, materials, deposition methods as the substrate 100 described with reference to FIG. 1A.

At block 304, the photo resist layer may be exposed to a light pattern to create exposed and unexposed regions, similar to the exposed regions 108 and unexposed regions 106 shown in FIG. 1B.

In various embodiments, block 306 through block 316 represent a cyclic dual development process to etch the photo resist layer that enhances etch profile control and endpoint detection accuracy. At block 306, a gas-based treatment may be performed using a first gas to modify material properties of the photo resist layer as described previously with reference to FIG. 1C. In various embodiments, the first gas may comprise the composition of the first gas 12 as described with reference to FIG. 1C. In some embodiments, an etch stop layer may form over the unexposed regions, as illustrated in FIG. 2A.

At block 308, the gas-based treatment may be completed by purging the first gas from the etch chamber. In some embodiments, a flow rate of the first gas may be reduced, for example, to zero, before the subsequent processing step.

At block 310, a second gas may be flowed into the etch chamber and a plasma may be generated from the second gas. In various embodiments, the second gas may comprise the components of the second gas as described with reference to FIG. 1D, including the inert gases and hydrogen-containing gases previously detailed. In one or more embodiments, the plasma may remove the etch stop layer and continue etching the unexposed region of the photo resist layer.

At block 314, an OES detector coupled to the etch chamber may collect optical emission data from the plasma within the etch chamber to track the etch progress. In various embodiments, the OES detector may comprise the configuration and detection capabilities as the OES detector described with reference to FIGS. 1C-1G.

The decision block 316 may determine whether an endpoint condition for etching the photo resist layer has been met based on the optical emission data collected by the OES detector. If the endpoint is not detected, the process may cycle back to block 306 for another iteration of gas-based treatment and plasma-based etch processes.

In various embodiments, each cycle (e.g., blocks 306-314) may remove a controlled thickness of material, allowing precise control of the etch profile. In various embodiments, the cyclic approach may be beneficial when the gas-based modification does not fully modify the material from top to bottom in a single cycle. The degree of modification throughout the thickness of the photo resist layer 104 may depend on factors such as the PEB conditions, material properties, and the extent of cross-linking in different regions. By performing multiple cycles of gas-based modification and plasma-based etch, the process may ensure complete modification and removal of the unexposed regions 106 throughout their entire thickness. In an embodiment, the cyclic process may be particularly advantageous for thicker photo resist layers or when high-temperature PEB conditions are used that increase cross-linking density. The cyclic approach provides multiple opportunities for endpoint checking and prevents over-etching. When the endpoint condition is satisfied at block 316, the process may proceed to block 318 where the cyclic dual development process for etching the photo resist layer may be stopped and the substrate may continue to subsequent fabrication steps. In various embodiments, the subsequent fabrication steps may comprise transferring the pattern formed in the photo resist layer to the underlayer and the layer to-be-patterned through additional etching processes as described in detail with reference to FIGS. 1F and 1G.

While FIG. 4 shows endpoint detection at block 314 following the plasma exposure step at block 312, it should be understood that data collection by the OES detector may occur continuously during the etch process. In various embodiments, the OES detector may actively collect and analyze optical emission data throughout the entire duration of plasma exposure to the photo resist layer. This continuous monitoring enables real-time tracking of the etch progress and immediate detection of endpoint conditions whenever they occur during the process. In alternative embodiments, the OES detector may analyze the optical emission data at a sampling rate between 1-10 Hz to ensure adequate temporal resolution for endpoint detection. In one or more embodiments, the endpoint detection algorithms may process the optical emission data in real-time, allowing the system to immediately stop the etch process upon endpoint detection, thereby preventing over-etching of the photo resist layer or underlying substrate layer. This continuous monitoring approach provides more precise process control compared to checking endpoint conditions only at discrete intervals or specific process steps.

FIG. 5 illustrates a schematic diagram of a processing system 40, which may be used to perform the dual development process of this disclosure to form a patterned MOR mask. The processing system 40 comprises several components designed to achieve precise control over the dual development process.

The processing system 40 comprises a processing chamber 450 which houses the main processing components. In various embodiments, the processing chamber 450 may be configured to maintain a vacuum environment for the dual development process. Within the processing chamber 450, a substrate holder 410 is positioned to support the substrate 100 during the dual development process. In various embodiments, the substrate holder 410 may be coupled to a temperature control system 460 to control the temperature of the substrate 100 during the dual development process. In an embodiment, the substrate holder 410 comprises a vacuum chuck or an electrostatic chuck (ESC), and the temperature control system 460 comprises a resistive heater or cooling elements to further control the temperature of the substrate 100 as desired. In one or more embodiments, the substrate holder 410 may be electrically connected to a system ground. In the embodiment illustrated in FIG. 5, the substrate holder 410 is electrically coupled with an RF bias power supply 434 configured to bias the substrate 100 during the plasma-based etch step of the dual development process.

At the top of the processing chamber 450 is a top plate 412, and at the bottom is a bottom plate 414. The top plate 412 comprises a gas inlet 422 coupled to a gas flow control system 420 for introducing various gases into the processing chamber 450 from a gas system 440. In various embodiments, the top plate 412 may be a showerhead gas injection system having a gas distribution assembly configured to form one or more gas distribution plenums or supply lines. In some embodiments, process gases may alternatively be introduced through side injection ports of the processing chamber 450. The bottom plate 414 comprises a gas outlet 424 coupled to the gas flow control system 420 for evacuating various gases from the processing chamber 450. In various embodiments, a dielectric sidewall 416 of the processing chamber 450 is disposed proximal a helical electrode 432, where the helical electrode 432 is coupled to an RF source power supply 430 to generate the plasma 140 used to perform the plasma-based etch step of the dual development process.

The gas delivery of the processing system 40 is controlled by the gas system 440. This system manages the flow of various gases, such as a processing gas 442, an additive gas 444, and an etch gas 446. In one or more embodiments, these gases may be combined to form the first gas or second gas mixtures used for the dual development process of this disclosure. In various embodiments, a purge gas may be provided by the gas system 440, such as an inert gas used to purge the processing chamber 450 between the gas-based modification step and the plasma-based etch step of the dual development process. The gas flow control system 420 may comprise various components such as high-pressure gas canisters, valves (e.g., throttle valves), pressure sensors, gas flow sensors, vacuum pumps, pipes, and electronically programmable controllers. The gas flow control system 420 allows for precise control of the chamber pressure during the dual development process. In various embodiments, the dual development process may configure pressures within the processing chamber 450 between about 10 mTorr and about 600 mTorr, with pressures greater than 200 mTorr preferred for shorter modification times.

At an appropriate position on a wall of the processing chamber 450, an optical port 490 may be disposed. An optical fiber cable 442 may receive and transmit optical signals from the plasma 140 within the processing chamber 450 to an OES detector 480. In various embodiments, the OES detector 480 may comprise a spectrometer that measures emission intensities across multiple wavelengths, particularly monitoring specific tin emission lines between 270 nm and 327 nm. The OES detector 480 may collect real-time optical emission data from the plasma 140 and analyze various plasma characteristics including chemical species concentrations through emission line intensities and reaction kinetics through temporal emission changes. In some embodiments, a survey scan using the OES detector 480 may be performed across a wavelength range, e.g., 200 nm to 700 nm, to generate baseline spectral data before etching the photo resist layer. The OES detector 480 may compare the real-time optical emission data with the baseline spectral data and determine an end point based on intensity changes in the real-time optical emission data relative to the baseline spectral data.

The OES detector 480 may be connected to a control unit 495, which may be coupled to a memory 485. In some embodiments, the control unit 495 and the chamber controller may be integrated as a single unit. The control unit 495 may comprise various electrical components required to analyze data from the OES detector 480 as well as feedback control of the processing system 40, such as a transceiver, an amplifier, an analog-to-digital converter (ADC), a filter, a memory, and a processor. In various embodiments, the OES detector 480 may be configured to perform a series of operations according to a command from the control unit 495: transmit the OES signals from the processing chamber 450 to the OES detector 480, OES data acquisition, filtering the OES data, and determining a characteristic of the plasma 140 at the processor, such as concentrations of tin-containing etch byproduct species. In certain embodiments, the OES detector 480 may be further configured to process the obtained raw OES data by averaging and/or smoothing prior to determining the characteristic of the plasma 140.

The temperature of the dual development process may be regulated by the temperature control system 460, which works in conjunction with the heating and cooling elements of the processing chamber 450 or the substrate holder 410. In various embodiments, the temperature control system 460 may be capable of achieving substrate temperatures between about −50° C. and 200° C.

The entire processing system 40 may be managed by the control unit 495, which coordinates the operation of all system components, while the memory 485 stores process recipes, parameters, and other relevant data of the dual development process.

The processing system 40 illustrates an embodiment capable of generating an inductively coupled plasma (ICP). In various embodiments, the processing chamber 450 may alternatively be configured to sustain a capacitively coupled plasma (CCP). Other suitable configurations such as electron cyclotron resonance (ECR) plasma sources and/or a helical resonator may also be used. The RF source power supply 430 and the RF bias power supply 434 may supply continuous wave (CW) or pulsed RF power to sustain the plasma 140. In various embodiments, the RF power, chamber pressure, substrate temperature, gas flow rates, and other process parameters may be implemented in accordance with a respective process recipe for an embodiment of the dual development process of this disclosure.

FIG. 6 illustrates exemplary data showing remaining thickness of both the exposed regions 108 and the unexposed region 106 of the photo resist layer 104 under various process conditions, in accordance with one embodiment.

Data point 502 may represent the initial thickness of the photo resist layer 104 in the exposed and unexposed regions. Data point 504 may represent the remaining thickness after the gas-based treatment using the first gas 12 as described above with reference to FIG. 1C. In one embodiment, the gas-based treatment may proceed for 15 s with the substrate 100 maintained at 10° C. Under this condition, the thickness of the unexposed region 106 shows limited reduction and the exposed region 108 maintains the thickness. Data point 506 may represent the remaining thickness after the dual development process, where the gas-based treatment represented in data point 504 may be followed by the plasma-based etch using the plasma 14 generated from the second gas as described above with reference to FIG. 1D. In one embodiment, the plasma-based etch may proceed for 15 s with the substrate 100 maintained at 10° C. In an embodiment, the second gas may comprise nitrogen and methane. After the plasma-based etch, the unexposed region 106 shows more reduced thickness while the thickness of the exposed region 108 is not changed. These results demonstrate the advantage of the dual development in selective etching the photo resist layer 104.

Data point 508 may represent the remaining thickness after the gas-based treatment at longer duration, for example, 30 s. Under longer gas-based treatment, the thickness of the unexposed region 106 may exhibit more but not sufficient reduction. Data point 510 may represent the thickness change after the plasma-based etch which follows the gas-based treatment of data point 508. The plasma-based etch may follow the conditions as described with reference to data point 506. Data point 506 shows that the dual development process demonstrates substantial thickness reduction of the unexposed region 106.

Data points 512 and 516 may represent the remaining thickness after the gas-based treatment at even longer durations. For example, data point 512 may be after 45 s gas-based treatment and data 516 may be after 60 s gas-based treatment. These data indicate that longer gas-based treatment continues leading to more etching of the unexposed region 106. In various embodiments, the extent of material removal during the gas-based treatment may be modulated by the PEB conditions applied prior to the dual development process. In an embodiment, higher PEB temperatures or longer PEB durations may increase cross-linking density in the exposed regions 108, which can reduce the removal rate of the unexposed regions 106 during the gas-based treatment step while maintaining the ability to selectively remove the unexposed regions 106 during the subsequent plasma-based etch step. Moreover, data point 520 may be the remaining thickness after gas-based treatment for 60 s at elevated temperature (e.g., 60° C.), where the higher temperature avoids formation of the etch stop layer observed at lower temperatures. In various embodiments, this elevated temperature condition may achieve full removal of the unexposed region 106 through gas-based treatment alone, however with reduced selectivity compared to the low-temperature dual development process. Comparing data point 520 with data points 514 and 518, the low-temperature dual development process demonstrates superior selectivity between the unexposed regions 106 and exposed regions 108 relative to the high-temperature gas-based treatment alone, highlighting the advantage of the dual development approach for MOR patterning.

Data points 514 and 518 may represent the remaining thickness after the plasma-based etch which follows the gas-based treatment of data points 512 and 516, respectively. The plasma-based etch may follow the conditions as described with reference to data point 506. In both data points 514 and 518, the unexposed region 106 is sufficiently etched, demonstrating the advantage of dual development process in selective etching the photo resist layer 104.

FIG. 7 illustrates exemplary optical emission data collected by the OES detector during the etch process, in accordance with one embodiment. In some embodiments, the data in FIG. 7 may be collected during etching the photo resist layer 104 comprising a layer of MOR which may comprise Sn. In some embodiments, the optical emission data in FIG. 7 may come from the byproducts 190 comprising SnHₓBr_{y} (1≤x≤4, 1≤y≤4) or SnH₄, which exhibit distinct optical emission characteristics in the plasma state.

In various embodiments, the spectra 602, 604, and 606 may represent the time evolution of optical emission during different stages of the development process. In various embodiments, spectra 602 and 604 may represent baseline spectral data collected during dummy wafer runs, where the plasma is struck under the same conditions but without any MOR present on the substrate, and therefore no Sn-containing species are being etched. In some embodiments, these dummy wafer runs may be used to establish a reference baseline of the plasma emission background in the absence of any tin-containing byproducts. Spectrum 606 may represent optical emission data collected during an actual dual development process run with MOR present on the substrate. The multiple distinct Sn emission peaks visible in spectrum 606 but absent in the baseline spectra 602 and 604 confirm the formation of volatile tin-containing species during the plasma-based etch step of the dual development process. The multiple distinct emission peaks (e.g., peaks indicated by the arrows in the spectrum) may correspond to Sn species being observed during the plasma process of the dual development as described in FIG. 1D. For example, these Sn emission peaks may appear at characteristic wavelengths: 270.5 nm, 284.0 nm, 286.0 nm, 300.5 nm, 303.5 nm, and 326.5 nm, representing different electronic transitions of tin-containing species in the plasma. The detection of these Sn-specific emission data during the development process confirms the formation of volatile tin-containing species, supporting the proposed mechanism of etch stop layer removal and MOR etching.

In various embodiments, the OES detector may collect real-time optical emission data from the plasma 14 and compare the real-time optical emission data with the baseline spectral data as illustrated in FIG. 7. An end point of the etch process may be determined based on intensity changes of the real-time optical emission data. In some embodiments, the end point may be determined when the Sn emission intensities drop below a preset threshold value, or when the Sn emission intensities reach the baseline intensity level established from dummy wafer runs as described above. The etch process may be stopped in response to determining the end point has been reached.

FIGS. 8A and 8B illustrate the effects of RF power on the plasma-based etch process, in accordance with one embodiment. In some embodiments, the optical emission spectra in FIG. 8A may be collected during etching the layer of MOR comprising Sn under different RF powers, where the RF powers may be applied to the RF power source 430 as described in FIG. 5. In a certain embodiment, the spectra 702, 704, and 706 may represent data collected at RF powers of 50 W, 75 W, and 150 W, respectively. In some embodiments, the optical emission data may come from the byproducts 190 comprising SnHₓBr_{y} (1≤x≤4, 1≤y≤4) or SnH₄, generated during the plasma-based etch process.

In various embodiments, FIG. 8B quantitatively demonstrates the correlation between RF power and etch performance. At 50 W RF power, corresponding to spectrum 702 showing weak Sn emission intensities, the remaining thickness of the unexposed region 106 after etch is 49.2 Å while the exposed region 108 is 103.1 Å. When RF power increases, for example, to 75 W, corresponding to spectrum 704 with moderate emission intensities, the remaining thickness of the unexposed region 106 after etch reduces to 26.0 Å. At higher RF power, for example, 150 W, corresponding to spectrum 706 exhibiting the strongest Sn emission peaks, the remaining thickness of the unexposed region 106 after etch may further reduce to 9.7 Å.

The correlation between optical emission data and etch performance demonstrated in FIGS. 8A and 8B supports the effectiveness of OES in monitoring the etch process. In various embodiments, the variation in optical emission intensities may directly correspond to quantifiable changes in etch performance. By real-time collecting the optical emission data from the plasma 14, the OES detector may track process variations and serve as a reliable monitoring tool for endpoint detection, ultimately improving manufacturing control and reliability.

FIGS. 9A and 9B illustrate exemplary data demonstrating advantages of the dual development process in terms of etch selectivity, in accordance with various embodiments. FIG. 9A shows remaining thickness of the non-exposed regions 106 after different etch processes, while FIG. 9B shows remaining thickness of the exposed regions 108 after the same etch processes.

In FIG. 9A, data point 1000 represents the incoming thickness of the non-exposed region 106 before any etch process. Data point 1002 represents the remaining thickness after the dual development process combining gas-based modification (FIG. 1C) and plasma-based etch (FIG. 1D). Data point 1004 represents the remaining thickness after plasma-based etch only without prior gas-based modification. Data point 1006 represents the remaining thickness after gas-based modification treatment only without subsequent plasma-based etch. The data demonstrates that the dual development process (data point 1002) achieves the highest etch rate for the non-exposed regions 106, removing substantially more material compared to either plasma-based etch alone (data point 1004) or gas-based modification alone (data point 1006).

In FIG. 9B, data point 1010 represents the incoming thickness of the exposed region 108 before any etch process. Data point 1012 represents the remaining thickness after the dual development process. Data point 1014 represents the remaining thickness after plasma-based etch only. Data point 1016 represents the remaining thickness after gas-based modification treatment only. The data demonstrates that the dual development process (data point 1012) results in minimal material removal from the exposed regions 108, comparable with thickness after gas-based modification treatment only, thereby preserving the integrity of these regions.

Comparing FIGS. 9A and 9B, the dual development process exhibits the highest etch rate for the non-exposed regions 106 while maintaining a low etch rate for the exposed regions 108 comparable to the gas-based treatment alone (data point 1016). In various embodiments, the plasma-based etch only process (data point 1014) shows a higher etch rate for the exposed regions 108 compared to the dual development process, resulting in lower selectivity. The dual development process therefore achieves significantly higher selectivity between the non-exposed regions 106 and exposed regions 108 compared to the plasma-based etch only approach, demonstrating the synergistic advantage of combining the gas-based modification step with the plasma-based etch step. The synergistic combination of gas-based modification followed by plasma-based etch enables more effective removal of the non-exposed regions while better preserving the exposed regions. In various embodiments, the gas-based modification step forms brominated species in the non-exposed regions that are subsequently converted to volatile hydrogen-containing compounds during the plasma-based etch step, facilitating enhanced material removal. This dual development approach provides improved process control and pattern fidelity for metal oxide photo resist processing.

Example embodiments of the invention are described below. Other embodiments can also be understood from the entirety of the specification as well as the claims filed herein.

Example 1. A method for etching a substrate, the method including: loading a substrate including a first layer in an etch chamber, the first layer including first regions and second regions, the first regions to be removed without removing the second regions; flowing a first gas into the etch chamber to chemically modify the first regions; after reducing a flow rate of the first gas, flowing a second gas into the etch chamber; generating a plasma from the second gas and exposing the first layer to the plasma to remove the first regions selectively with respect to the second regions; while exposing the first layer to the plasma, collecting optical emission data from the plasma using an optical emission spectroscopy (OES) detector coupled to the etch chamber; determining an end point for the etching of the first layer based on the optical emission data; and stopping the etching of the first layer in response to determining the end point.

Example 2. The method of example 1, further including: etching a second layer disposed under the first layer using the first layer as an etch mask.

Example 3. The method of one of examples 1 or 2, further including: exposing the first layer to an actinic radiation through an optical mask to form the first regions that are unexposed and the second regions that are exposed to the actinic radiation.

Example 4. The method of example 2, where the substrate further includes an underlayer disposed between the first layer and the second layer, further including transferring a pattern in the first layer to the underlayer.

Example 5. The method of one of examples 1 to 4, where the first layer includes a layer of metal oxide photo resist.

Example 6. The method of example 5, where the layer of metal oxide photo resist includes tin (Sn), antimony (Sb), hafnium (Hf), zirconium (Zr), or zinc (Zn).

Example 7. The method of one of examples 1 to 6, where the first gas includes a halogen-containing gas, and where the second gas includes an inert gas and a hydrogen-containing gas, and where flowing the first gas and exposing the first layer to the plasma are performed at a substrate temperature between −50° C. and 10° C.

Example 8. The method of example 7, where the halogen-containing gas includes hydrogen bromide (HBr), hydrogen chloride (HCl), hydrogen iodide (HI), boron trichloride (BCl₃), or boron tribromide (BBr₃), and where the inert gas includes nitrogen (N₂), and where the hydrogen-containing gas includes methane (CH₄), ethane (C₂H₆), propane (C₃H₈), butane (C₄H₁₀), hydrogen (H₂), ammonia (NH₃), or hydrazine (N₂H₄).

Example 9. The method of one of examples 1 to 8, where flowing the first gas chemically modifies the first regions by forming brominated metal compounds, and where the plasma converts the brominated metal compounds into hydrogen-containing metal species.

Example 10. A method for processing a substrate, the method including: performing a cyclic dual development process in an etch chamber, one cycle of the cyclic dual development process including: chemically modifying a first layer by flowing a first gas into the etch chamber, flowing a second gas into the etch chamber, generating a plasma from the second gas in the etch chamber, collecting optical emission data from the plasma using an optical emission spectroscopy (OES) detector, and determining an end point for the cyclic dual development process based on the optical emission data; stopping the cyclic dual development process in response to determining the end point has been reached; and transferring the pattern in the first layer to a second layer of the substrate through additional etching processes.

Example 11. The method of example 10, further including: before performing the cyclic dual development process, forming exposed regions and unexposed regions in the first layer by exposing the substrate to a light pattern.

Example 12. The method of example 11, where the plasma removes etch-inhibiting species formed on the unexposed regions of the first layer during flowing the first gas.

Example 13. The method of one of examples 10 to 12, where the first layer includes a layer of metal oxide photo resist.

Example 14. The method of example 13, where the layer of metal oxide photo resist includes tin (Sn), antimony (Sb), hafnium (Hf), zirconium (Zr), or zinc (Zn).

Example 15. The method of one of examples 10 to 14, where the first gas includes a halogen-containing gas.

Example 16. The method of one of examples 10 to 15, where the second gas includes nitrogen (N₂) and a hydrogen-containing gas.

Example 17. A method of endpoint detection during an etch process, the method including: performing a scan using an optical emission spectroscopy (OES) detector across a wavelength range to generate baseline spectral data before etching a photo resist layer in an etch chamber; flowing a first gas into the etch chamber to chemically modify the photo resist layer; purging the etch chamber of the first gas and flowing a second gas into the etch chamber; generating a plasma from the second gas to continue etching the photo resist layer; collecting real-time optical emission data from the plasma; and determining an end point based on intensity changes of the real-time optical emission data relative to the baseline spectral data.

Example 18. The method of example 17, where flowing the first gas chemically modifies the photo resist layer by forming brominated metal compounds in the photo resist layer.

Example 19. The method of one of examples 17 or 18, where the first gas includes a halogen-containing gas, and where the second gas includes nitrogen (N₂) and a hydrogen-containing gas.

Example 20. The method of one of examples 17 to 19, further including: exposing the photo resist layer to an actinic radiation; and performing a post-exposure bake on the photo resist layer after the exposing.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-9B may be combined in further embodiments. It is therefore intended that the appended claims encompass any such modifications or embodiments.

What is claimed is:

1. A method for etching a substrate, the method comprising:
loading a substrate comprising a first layer in an etch chamber, the first layer comprising first regions and second regions, the first regions to be removed without removing the second regions;
flowing a first gas into the etch chamber to chemically modify the first regions;
after reducing a flow rate of the first gas, flowing a second gas into the etch chamber;
generating a plasma from the second gas and exposing the first layer to the plasma to remove the first regions selectively with respect to the second regions;
while exposing the first layer to the plasma, collecting optical emission data from the plasma using an optical emission spectroscopy (OES) detector coupled to the etch chamber;
determining an end point for the etching of the first layer based on the optical emission data; and
stopping the etching of the first layer in response to determining the end point.

2. The method of claim 1, further comprising:
etching a second layer disposed under the first layer using the first layer as an etch mask.

3. The method of claim 1, further comprising:
exposing the first layer to an actinic radiation through an optical mask to form the first regions that are unexposed and the second regions that are exposed to the actinic radiation.

4. The method of claim 2, wherein the substrate further comprises an underlayer disposed between the first layer and the second layer, further comprising transferring a pattern in the first layer to the underlayer.

5. The method of claim 1, wherein the first layer comprises a layer of metal oxide photo resist.

6. The method of claim 5, wherein the layer of metal oxide photo resist comprises tin (Sn), antimony (Sb), hafnium (Hf), zirconium (Zr), or zinc (Zn).

7. The method of claim 1, wherein the first gas comprises a halogen-containing gas, and wherein the second gas comprises an inert gas and a hydrogen-containing gas, and wherein flowing the first gas and exposing the first layer to the plasma are performed at a substrate temperature between −50° C. and 10° C.

8. The method of claim 7, wherein the halogen-containing gas comprises hydrogen bromide (HBr), hydrogen chloride (HCl), hydrogen iodide (HI), boron trichloride (BCl₃), or boron tribromide (BBr₃), and wherein the inert gas comprises nitrogen (N₂), and wherein the hydrogen-containing gas comprises methane (CH₄), ethane (C₂H₆), propane (C₃H₈), butane (C₄H₁₀), hydrogen (H₂), ammonia (NH₃), or hydrazine (N₂H₄).

9. The method of claim 1, wherein flowing the first gas chemically modifies the first regions by forming brominated metal compounds, and wherein the plasma converts the brominated metal compounds into hydrogen-containing metal species.

10. A method for processing a substrate, the method comprising:
performing a cyclic dual development process in an etch chamber, one cycle of the cyclic dual development process comprising:
chemically modifying a first layer by flowing a first gas into the etch chamber,
flowing a second gas into the etch chamber,
generating a plasma from the second gas in the etch chamber,
collecting optical emission data from the plasma using an optical emission spectroscopy (OES) detector, and
determining an end point for the cyclic dual development process based on the optical emission data;
stopping the cyclic dual development process in response to determining the end point has been reached; and
transferring a pattern in the first layer to a second layer of the substrate through additional etching processes.

11. The method of claim 10, further comprising:
before performing the cyclic dual development process, forming exposed regions and unexposed regions in the first layer by exposing the substrate to a light pattern.

12. The method of claim 11, wherein the plasma removes etch-inhibiting species formed on the unexposed regions of the first layer during flowing the first gas.

13. The method of claim 10, wherein the first layer comprises a layer of metal oxide photo resist.

14. The method of claim 13, wherein the layer of metal oxide photo resist comprises tin (Sn), antimony (Sb), hafnium (Hf), zirconium (Zr), or zinc (Zn).

15. The method of claim 10, wherein the first gas comprises a halogen-containing gas.

16. The method of claim 10, wherein the second gas comprises nitrogen (N₂) and a hydrogen-containing gas.

17. A method of endpoint detection during an etch process, the method comprising:
performing a scan using an optical emission spectroscopy (OES) detector across a wavelength range to generate baseline spectral data before etching a photo resist layer in an etch chamber;
flowing a first gas into the etch chamber to chemically modify the photo resist layer;
purging the etch chamber of the first gas and flowing a second gas into the etch chamber;
generating a plasma from the second gas to continue etching the photo resist layer;
collecting real-time optical emission data from the plasma; and
determining an end point based on intensity changes of the real-time optical emission data relative to the baseline spectral data.

18. The method of claim 17, wherein flowing the first gas chemically modifies the photo resist layer by forming brominated metal compounds in the photo resist layer.

19. The method of claim 17, wherein the first gas comprises a halogen-containing gas, and wherein the second gas comprises nitrogen (N₂) and a hydrogen-containing gas.

20. The method of claim 17, further comprising:
exposing the photo resist layer to an actinic radiation; and
performing a post-exposure bake on the photo resist layer after exposure.
